(19) United States
(12) Patent Application Publication
(10) Pub. No.: US 2010/0283385 A1
(43) Pub. Date: Nov. 11, 2010

(54) ORGANIC EL DEVICE

(75) Inventors: Norihisa Maeda, Ishikawa-gun (JP); Takeshi Ikeda, Hakusan-shi (JP)

Correspondence Address: OBLON, SPIVAK, MCCLELLAND MAIER & NEUSTADT, L.L.P., 1940 DUKE STREET, ALEXANDRIA, VA, 22314, US

(73) Assignee: Toshiba Mobile Display Co., Ltd., Fukaya-shi (JP)

(21) Appl. No.: 12/771,292

(22) Filed: Apr. 30, 2010

(30) Foreign Application Priority Data
May 11, 2009 (JP) 2009-114797

(51) Int. Cl. H01L 51/54

(52) U.S. Cl. 313/504

(57) ABSTRACT

According to one embodiment, an organic EL device includes a first organic EL element having a first pixel electrode, a counter-electrode, and a first organic multiplayer structure, a second organic EL element having a second pixel electrode, a counter-electrode, and a second organic multiplayer structure, a third organic EL element having a third pixel electrode, a counter-electrode, and a third organic multiplayer structure. The first organic multiplayer structure includes a first organic layer, a first hole transport layer, and a first electron transport layer. The second organic multiplayer structure includes a second organic layer, a first hole transport layer, and a first electron transport layer. The third organic multiplayer structure includes a third organic layer, a first hole transport layer, a second hole transport layer, a first electron transport layer, and a second electron transport layer.

### CROSS-REFERENCE TO RELATED APPLICATIONS

This application is based upon and claims the benefit of priority from Japanese Patent Application No. 2009-114797, filed May 11, 2009; the entire contents of which are incorporated herein by reference.

### FIELD

Embodiments described herein relate generally to an organic electroluminescence (EL) device.

### BACKGROUND

In recent years, display devices using organic electroluminescence (EL) elements have vigorously been developed, which have features of self-emission, a high response speed, a wide viewing angle and a high contrast, and which can realize small thickness and light weight.

Jpn. Pat. Appln. KOKAI Publication No. 2003-157973, for instance, discloses a technique wherein a light-reflective cathode is formed in each of organic EL elements of red (R), green (G) and blue (B), and thereafter a first electron injection layer, which is common to the three-color organic EL elements, is formed. Subsequently, a second electron injection layer is stacked only in the blue organic EL element, and further an electron transport layer, which is common to the three-color organic EL elements, is formed, and a light emission layer is formed in each of the organic EL elements by using a shadow mask. Thereafter, a hole transport layer, a hole injection layer and a light-transmissive anode, which are common to the three-color organic EL elements, are formed.

In such organic EL elements, there has been a demand for the optimization of the organic multilayer structure including the organic layer that functions as a light emission layer, a hole transport layer, etc.

### BRIEF DESCRIPTION OF THE DRAWINGS

FIG. 1 is a cross-sectional view which schematically shows an example of the structure that is adoptable in an organic EL display device according to an embodiment;

FIG. 2 is a plan view which schematically shows an example of arrangement of pixels, which is adoptable in the organic EL display device shown in FIG. 1;

FIG. 3 schematically shows an example of the structure that is adoptable in first to third organic EL elements which are included in the organic EL display device shown in FIG. 1;

FIG. 4 is a cross-sectional view of an array substrate including the first to third organic EL elements shown in FIG. 3;

FIG. 5 is a graph showing a first simulation result;

FIG. 6 is a graph showing a second simulation result;

FIG. 7 schematically shows another example of the structure that is adoptable in the first to third organic EL elements which are included in the organic EL display device shown in FIG. 1; and

FIG. 8 is a cross-sectional view of an array substrate including the first to third organic EL elements shown in FIG. 7.

### DETAILED DESCRIPTION

In general, according to one embodiment, an organic EL device includes a first organic EL element, a second organic EL element, and a third organic EL element. The first organic EL element has a first light emission wavelength. The first organic EL element includes A) a first pixel electrode, B) a counter-electrode, and C) a first organic multiplayer structure including a first organic layer disposed between the first pixel electrode and the counter-electrode and functioning as a light emission layer, a first hole transport layer disposed between the first pixel electrode and the first organic layer, and a first electron transport layer disposed between the first organic layer and the counter-electrode. The second organic EL element has a less thickness than the first organic EL element and a second light emission wavelength which is less than the first light emission wavelength. The second organic EL element including A) a second pixel electrode, B) a counter-electrode extending from the first organic EL element, and C) a second organic multiplayer structure including a second organic layer disposed between the second pixel electrode and the counter-electrode and functioning as a light emission layer, a first hole transport layer extending from the first organic EL element and disposed between the second pixel electrode and the second organic layer, and a first electron transport layer extending from the first organic EL element and disposed between the second organic layer and the counter-electrode. The third organic EL element has a greater thickness than the first organic EL element and a third light emission wavelength which is less than the second light emission wavelength. The third organic EL element including A) a third pixel electrode, B) a counter-electrode extending from the second organic EL element, and C) a third organic multiplayer structure including a third organic layer disposed between the third pixel electrode and the counter-electrode and functioning as a light emission layer, a first hole transport layer extending from the second organic EL element and disposed between the third pixel electrode and the third organic layer, a second hole transport layer disposed between the third pixel electrode and the third organic layer, a first electron transport layer extending from the second organic EL element and disposed between the third organic layer and the counter-electrode, and a second electron transport layer disposed between the third organic layer and the counter-electrode.

According to another embodiment, an organic EL device includes a first organic EL element, a second organic EL element, and a third organic EL element. The first organic EL element has a first light emission wavelength. The first organic EL element includes A) a first pixel electrode, B) a counter-electrode, and C) a first organic multiplayer structure including a first organic layer disposed between the first pixel electrode and the counter-electrode and functioning as a light emission layer, a first hole transport layer disposed between the first pixel electrode and the first organic layer, a second organic layer disposed between the first organic layer and the counter-electrode and functioning as a carrier transport layer, and a third organic layer disposed between the second organic layer and the counter-electrode and functioning as a carrier transport layer. The second organic EL element has a second light emission wavelength which is less than the first light emission wavelength. The second organic EL element includes A) a second pixel electrode, B) a counter-electrode extending from the first organic EL element, and C) a second organic multiplayer structure including a second organic layer extending from the first organic EL element, disposed between the second pixel electrode and the counter-electrode and functioning as a light emission layer, a first hole transport layer extending from the first organic EL element and disposed between the second pixel electrode and the second organic layer, and a third organic layer extending from the first organic EL element, disposed between the second organic layer and the counter-electrode and functioning as a carrier transport layer. The third organic EL element has a third light emission wavelength which is less than the second light emission wavelength. The third organic EL element includes A) a third pixel electrode, B) a counter-electrode extending from the second organic EL element, and C) a third organic multiplayer structure including a first organic layer extending from the first organic EL element, disposed between the third pixel electrode and the counter-electrode and functioning as a carrier transport layer, a first hole transport layer extending from the second organic EL element and disposed between the third pixel electrode and the first organic layer, a second organic layer extending from the second organic EL element, disposed between the first organic layer and the counter-electrode and functioning as a carrier transport layer, a second hole transport layer disposed between the second organic layer and the counter-electrode, and a third organic layer extending from the second organic EL element, disposed between the second hole transport layer and the counter-electrode and functioning as a light emission layer.

An embodiment will now be described in detail with reference to the accompanying drawings. In the drawings, structural elements having the same or similar functions are denoted by like reference numerals, and an overlapping description is omitted.

In the present embodiment, as an example of the organic EL device, a description is given of an organic EL display device which adopts an active matrix driving method.

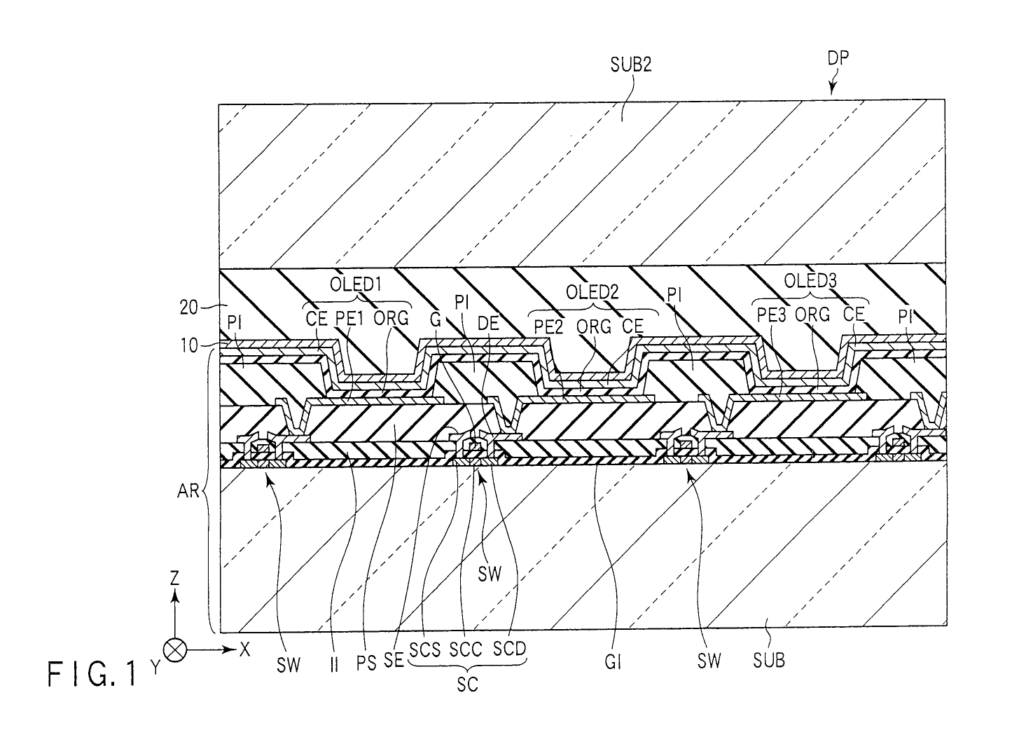

FIG. 1 is a cross-sectional view which schematically shows an example of the structure that is adoptable in the organic EL display device according to the embodiment.

A display panel DP, which constitutes the organic EL display device, includes an array substrate AR in which switching transistors SW and first to third organic EL elements OLED1 to OLED 3 are formed.

A semiconductor layer SC of the switching transistor SW is disposed on an insulative substrate SUB such as a glass substrate. The semiconductor layer SC is formed of, e.g. polysilicon. In the semiconductor layer SC, a source region SCS and a drain region SCD are formed, with a channel region SCC being interposed.

The semiconductor layer SC is coated with a gate insulation film GI. The gate insulation film GI is also disposed on the insulative substrate SUB. A gate electrode G of the switching transistor SW is disposed on the gate insulation film GI immediately above the channel region SCC. In this example, the switching transistor SW is a top-gate-type p-channel thin-film transistor.

The gate electrode G is coated with an interlayer insulation film II. The interlayer insulation film II is also formed on the gate insulation film GI. A source electrode SE and a drain electrode DE of the switching transistor SW are disposed on the interlayer insulation film II. The source electrode SE is connected to the source region SCS of the semiconductor layer SC. The drain electrode DE is connected to the drain region SCD of the semiconductor layer SC. The source electrode SE and drain electrode DE are coated with a passivation film PS. The passivation film PS is also formed on the interlayer insulation film II.

A first pixel electrode PE1 of the first organic EL element OLED1, a second pixel electrode PE2 of the second organic EL element OLED2, and a third pixel electrode PE3 of the third organic EL element OLED3 are disposed on the passivation film PS. Each of the first to third pixel electrodes PE1 to PE3 is electrically connected to the drain electrode DE of the switching element SW, and corresponds to an anode in this example.

A partition wall PI is formed on the passivation film PS. The partition wall PI is disposed in a lattice shape in a manner to surround the entire periphery of each of the first to third pixel electrodes PE1 to PE3. The partition wall PI may be disposed in a stripe shape extending in the Y direction between the first to third pixel electrodes PE1 to PE3. The partition wall PI is disposed between the first organic EL element OLED1 and the second organic EL element OLED2 and isolates both EL elements. In addition, the partition wall PI is disposed between the second organic EL element OLED2 and the third organic EL element OLED3 and isolates both EL elements. Furthermore, the partition wall PI is disposed between the third organic EL element OLED3 and the first organic EL element OLED1 and isolates both EL elements.

An organic multilayer structure ORG is disposed on each of the first to third pixel electrodes PE1 to PE3. The organic multilayer structure ORG includes at least one continuous film which extends over the display region including the first to third organic EL elements OLED1 to OLED3. The details of the organic multilayer structure ORG will be described later.

The organic multiplayer structure ORG is coated with a counter-electrode CE. In this example, the counter-electrode CE corresponds to a cathode. The counter-electrode CE is a continuous film which extends over the display region including the first to third organic EL elements OLED1 to OLED3.

Although FIG. 1 shows one first organic EL element OLED1, one second organic EL element OLED2 and one third organic EL element OLED3, these organic EL elements OLED1, OLED2 and OLED3 are repeatedly disposed in the X direction. Specifically, another first organic EL element OLED1 is disposed adjacent to the third organic EL element OLED3 that is shown on the right side part of FIG. 1. Similarly, another third organic EL element OLED3 is disposed adjacent to the first organic EL element OLED1 that is shown on the left side part of FIG. 1.

The sealing of the first to third organic EL elements OLED1 to OLED3 may be effected by bonding a counter-substrate SUB2, to which a desiccant is attached, by means of a sealant which is applied to the periphery of the display region. Alternatively, the sealing of the first to third organic EL elements OLED1 to OLED3 may be effected by bonding the counter-substrate SUB2 by means of frit glass. In the example shown, the display panel DP includes a protection film 10 which is formed of an inorganic material covering the first to third organic EL elements OLED1 to OLED3, and a filling layer 20 which is filled between the counter-substrate SUB2 and the protection film 10.

In the present embodiment, the first to third organic EL elements OLED1 to OLED3 are configured to have different emission light colors.

In this example, the emission light color of the first organic EL element OLED1 is red, the emission light color of the second organic EL element OLED2 is green, and the emission light color of the third organic EL element OLED3 is blue. The color of light with a major wavelength in the range of wavelengths of 400 nm to 490 nm is defined as blue; the color of light with a major wavelength, which is greater than 490 nm and less than 595 nm, is defined as green; and the color of light with a major wavelength in the range of wavelengths of 595 nm to 800 nm is defined as red. The range of major wavelength between 595 nm and 800 nm is defined as a first wavelength band, the range of major wavelength, which is greater than 490 nm and less than 595 nm, is defined as a second wavelength band, and the range of major wavelength between 400 nm and 490 nm is defined as a third wavelength band.

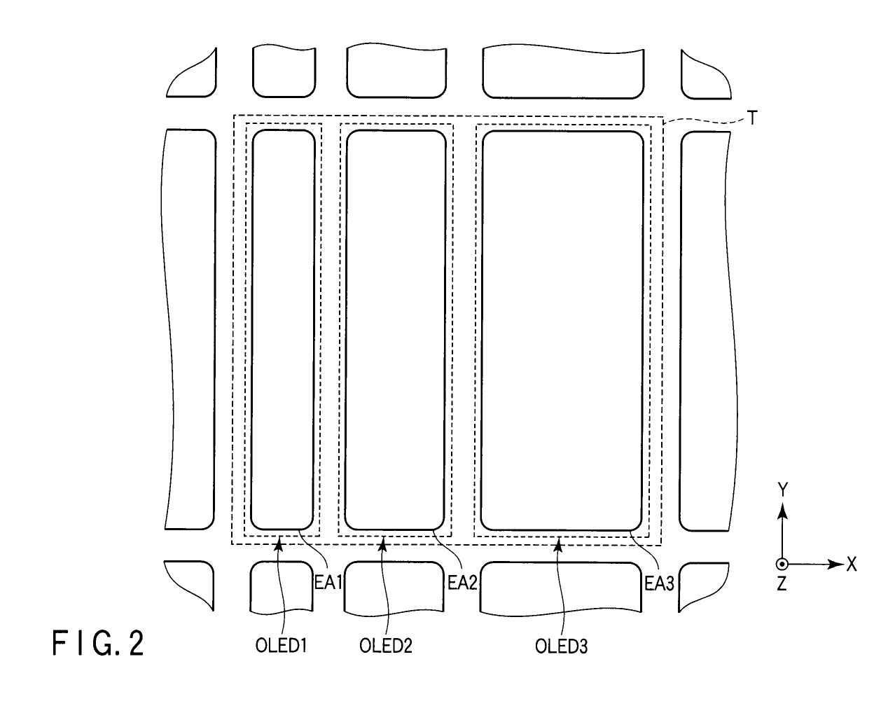

FIG. 2 shows a structure example of a triplet T. The triplet T is formed in a square shape with substantially equal lengths in the X direction and Y direction. The triplet T is composed of a first organic EL element OLED1, a second organic EL element OLED2, and a third organic EL element OLED3.

Each of a light emission section EA1 of the first organic EL element OLED1, a light emission section EA2 of the second organic EL element OLED2 and a light emission section EA3 of the third organic EL element OLED3 is formed in a rectangular shape extending in the Y direction. The relationship in area between the light emission sections EA1 to EA3 is, for example, as follows:

the area of first light emission section EA1<the area of second light emission section EA2<the area of third light emission section EA3.

An example of the ratio in area between the light emission sections EA1 to EA3 is as follows:

EA1:EA2:EA3=1:1.3:2.7.

In this example, since the lengths of the light emission sections EA1 to EA3 in the Y direction are substantially equal, the above-described ratio in area is set according to the lengths of the light emission sections EA1 to EA3 in the X direction.

The areas of the light emission sections EA1 to EA3 may be varied so as to obtain desired characteristics. The relationship in area between the light emission sections EA1 to EA3 is not limited to the example shown in FIG. 2, and may be made substantially equal to each other.

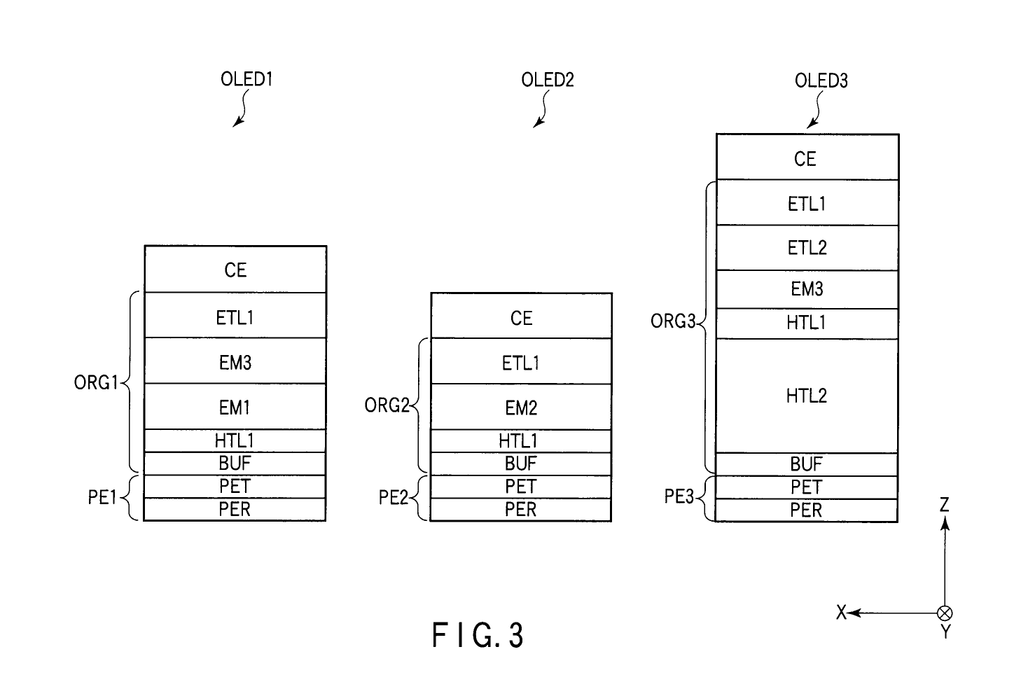

FIG. 3 schematically shows the structures of first to third organic EL elements OLED1 to OLED3 in a first embodiment.

The first organic EL element OLED1 includes a first organic multilayer structure ORG1 between a first pixel electrode PE1 and a counter-electrode CE. Specifically, the first pixel electrode PE1 includes a reflective layer PER and a transmissive layer PET which is disposed on the reflective layer PER. The first organic multilayer structure ORG1 is disposed on the first pixel electrode PE1. The first organic multilayer structure ORG1 includes a buffer layer BUF which is disposed on the transmissive layer PET, a first hole transport layer HTL1 which is disposed on the buffer layer BUF, a first organic layer EM1 which is disposed on the first hole transport layer HTL1 and functions as a light emission layer, a third organic layer EM3 which is disposed on the first organic layer EM1, and a first electron transport layer ETL1 which is disposed on the third organic layer EM3. The counter-electrode CE is disposed on the first electron transport layer ETL1 of the first organic multilayer structure ORG1.

The second organic EL element OLED2 includes a second organic multilayer structure ORG2 between a second pixel electrode PE2 and a counter-electrode CE. Specifically, the second pixel electrode PE2 includes a reflective layer PER and a transmissive layer PET which is disposed on the reflective layer PER. The second organic multilayer structure ORG2 is disposed on the second pixel electrode PE2. The second organic multilayer structure ORG2 includes a buffer layer BUF which is disposed on the transmissive layer PET, a first hole transport layer HTL1 which is disposed on the buffer layer BUF, a second organic layer EM2 which is disposed on the first hole transport layer HTL1 and functions as a light emission layer, and a first electron transport layer ETL1 which is disposed on the second organic layer EM2. The counter-electrode CE is disposed on the first electron transport layer ETL1 of the second organic multilayer structure ORG2.

The third organic EL element OLED3 includes a third organic multilayer structure ORG3 between a third pixel electrode PE3 and a counter-electrode CE. Specifically, the third pixel electrode PE3 includes a reflective layer PER and a transmissive layer PET which is disposed on the reflective layer PER. The third organic multilayer structure ORG3 is disposed on the third pixel electrode PE3. The third organic multilayer structure ORG3 includes a buffer layer BUF which is disposed on the transmissive layer PET, a second hole transport layer HTL2 which is disposed on the buffer layer BUF, a first hole transport layer HTL1 which is disposed on the second hole transport layer HTL2, a third organic layer EM3 which is disposed on the first hole transport layer HTL1 and functions as a light emission layer, a second electron transport layer ETL2 which is disposed on the third organic layer EM3, and a first electron transport layer ETL1 which is disposed on the second electron transport layer ETL2. The counter-electrode CE is disposed on the first electron transport layer ETL1 of the third organic multilayer structure ORG3.

The first to third pixel electrodes PE1 to PE3 of the first to third organic EL elements OLED1 to OLED3 have the same structure, that is, the two-layer structure in which the transmissive layer PET is stacked on the reflective layer PER. The reflective layer PER is formed of, e.g. silver (Ag). Alternatively, the reflective layer PER may be formed of other electrically conductive material with light reflectivity, such as aluminum (Al). The transmissive layer PET, which is disposed between the reflective layer PER and the buffer BUF, is formed of, e.g. indium tin oxide (ITO). Alternatively, the transmissive layer PET may be formed of other electrically conductive material with light transmissivity, such as indium zinc oxide (IZO). The first to third pixel electrodes PE1 to PE3 have substantially equal thickness.

The first hole transport layer HTL1 is formed of, e.g. N,N′-diphenyl-N,N′-bis(1-naphtylphenyl)-1,1′-biphenyl-4,4′-diamine (α-NPD). Alternatively, the first hole transport layer HTL1 may be formed of other material. The first hole transport layers HTL1 of the first to third organic EL elements OLED1 to OLED3 have substantially equal thickness.

The second hole transport layer HTL2 of the third organic EL element OLED3 may be formed of the same material as the first hole transport layer HTL1, but it may be formed of other material having a different hole mobility.

The first electron transport layer ETL1 is formed of, e.g. 8-quinolinol aluminum complex (Alq₃), but it may be formed of other material. The first electron transport layers ETL1 of the first to third organic EL elements OLED1 to OLED3 have substantially equal thickness.

The second electron transport layer ETL2 of the third organic EL element OLED3 can be formed of the same material as the first electron transport layer ETL1, but it may be formed of other material having a different electron mobility.

Each of the first to third organic layers EM1 to

EM3 includes a host material. As the host material, for instance, 4,4′-bis(2,2′-diphenyl-ethen-1-yl)-diphenyl (BPVBI) is usable, but other material may be used.

The first organic layer EM1 includes a first light-emitting material (dopant material) which is formed of a luminescent organic compound or composition having a central light emission wavelength in red wavelengths. As the first light-emitting material, for instance, 4-(Dicyanomethylene)-2-methyl-6-(julolidin-4-yl-vinyl)-4H-pyran (DCM2) is usable, but other material may be used. In the first organic EL element OLED1, since the first organic layer EM1 functions as a light emission layer, the first organic EL element OLED1 emits red light having an emission light wavelength in the first wavelength band.

The second organic layer EM2 includes a second light-emitting material (dopant material) which is formed of a luminescent organic compound or composition having a central light emission wavelength in green wavelengths. As the second light-emitting material, for instance, Alq₃ is usable, but other material may be used. In the second organic EL element OLED2, since the second organic layer EM2 functions as a light emission layer, the second organic EL element OLED2 emits green light having an emission light wavelength in the second wavelength band.

The third organic layer EM3 includes a third light-emitting material (dopant material) which is formed of a luminescent organic compound or composition having a central light emission wavelength in blue wavelengths. As the third light-emitting material, for instance, bis[(4,6-difluorophenyl)-pyridinato-N,C2′](picorinate)iridium(III) (FIrpic) is usable, but other material may be used. In the third organic EL element OLED3, since the third organic layer EM3 functions as a light emission layer, the third organic EL element OLED3 emits blue light having an emission light wavelength in the third wavelength band.

The first light-emitting material, second light-emitting material and third light-emitting material may be fluorescent materials or phosphorescent materials.

The counter-electrode CE has a single-layer structure which is composed of a semi-transmissive layer. The counter-electrode CE is formed of, e.g. magnesium-silver, but it may be formed of other electrically conductive material. The counter-electrodes CE of the first to third organic EL elements OLED1 to OLED3 have substantially equal thickness.

In the first embodiment, each of the first to third organic EL elements OLED1 to OLED3 adopts a top-emission-type structure in which emission light is extracted from the counter-electrode side. In addition, each of the first to third organic EL elements OLED1 to OLED3 adopts a micro-cavity structure which is composed of each reflective layer PER of the first to third pixel electrodes PE1 to PE3, and the counter-electrode CE that is formed of a semi-transmissive layer. In the meantime, in the case where either of the cathode and anode, which sandwich the first to third organic multiplayer structures ORG1 to ORG3, is composed of only a transparent electrode, the micro-cavity structure cannot be obtained.

In the first embodiment, the thickness of the second organic EL element OLED2 is less than that of the first organic EL element OLED1. The thickness of the third organic EL element OLED3 is greater than that of the first organic EL element OLED1. The thickness (or film thickness), in this context, corresponds to the distance in a normal direction, that is, in the Z direction. The thickness of each of the first to third organic EL elements OLED1 to OLED3 corresponds to the distance between each of the first to third pixel electrodes PE1 to PE3 and the counter-electrode CE along the Z direction.

The relationship in thickness between the first to third organic EL elements OLED1 to OLED3 is as follows:

the second organic EL element OLED2<the first organic EL element OLED1<the third organic EL element OLED3.

The following relationship is established between the total thickness T1 of the first organic multilayer structure ORG1 and transmissive layer PET between the reflective layer PER and the counter-electrode CE that is the semi-transmissive layer of the first organic EL element OLED1, the total thickness T2 of the second organic multilayer structure ORG2 and transmissive layer PET between the reflective layer PER and the counter-electrode CE that is the semi-transmissive layer of the second organic EL element OLED2, and the total thickness T3 of the third organic multilayer structure ORG3 and transmissive layer PET between the reflective layer PER and the counter-electrode CE that is the semi-transmissive layer of the third organic EL element OLED3:

T2<T1<T3.

In the above-described structure, the first organic EL element OLED 1 and the second organic EL element OLED2 may adopt device structures which make use of the interference effect of the same order. For example, the first organic EL element OLED 1 and the second organic EL element OLED2 may adopt device structures which make use of the interference effect of a 0th order.

The third organic EL element OLED3 may adopt a device structure which makes use of the interference effect of a higher order than the first organic EL element OLED 1 and the second organic EL element OLED2. For example, the third organic EL element OLED3 may adopt a device structure which makes use of the interference effect of a first order.

The difference in thickness between the first to third organic EL elements OLED1 to OLED3 is created by the film thicknesses of the first organic layer EM1, second organic layer EM2, third organic layer EM3, second hole transport layer HTL2 and second electron transport layer ETL2, since the thickness of the first electron transport layer ETL1 is common between the first to third organic EL elements OLED1 to OLED3.

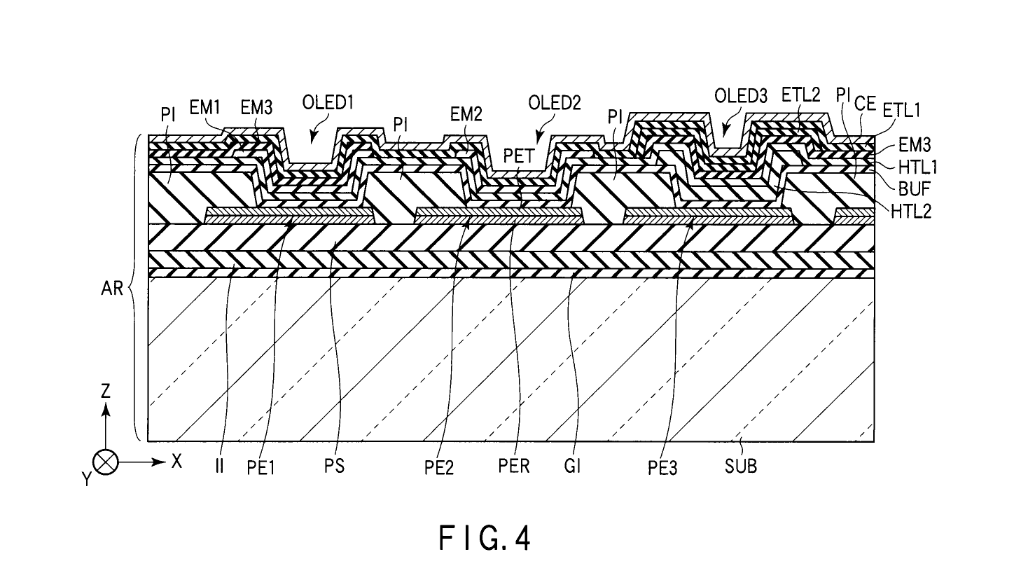

FIG. 4 schematically shows the cross-sectional structure of the array substrate AR including the first to third organic EL elements OLED1 to OLED3 according to the first embodiment. In FIG. 4, the dimensions in the X direction are different from those in FIG. 2, in order to clarify the structures of the first to third organic EL elements OLED1 to OLED3. FIG. 4 shows the cross-sectional structure which does not include the switching transistors SW.

As shown in FIG. 4, the gate insulation film GI, interlayer insulation film II and passivation film PS are disposed between the substrate SUB and the reflective layer PER of each of the first to third organic EL elements OLED1 to OLED3. The reflective layer PER of each of the first to third organic EL elements OLED1 to OLED3 is disposed on the passivation film PS. The transmissive layer PET of each of the first to third organic EL elements OLED1 to OLED3 is disposed on the reflective layer PER.

The buffer layer BUF extends over the first to third organic EL elements OLED1 to OLED3 and is disposed on the transmissive layer PET of the first pixel electrode PE1, the transmissive layer PET of the second pixel electrode PE2 and the transmissive layer PET of the third pixel electrode PE3. In addition, the buffer layer BUF is disposed on the partition wall PI which is disposed between the first organic EL element OLED1 and the second organic EL element OLED2, between the second organic EL element OLED2 and the third organic EL element OLED3, and between the third organic EL element OLED3 and the first organic EL element OLED1. Specifically, the buffer layer BUF is a continuous film spreading over the display region and is disposed common to the first to third organic EL elements OLED1 to OLED3.

The second hole transport layer HTL2 is disposed on the buffer layer BUF of the third organic EL element OLED3. Part of the second hole transport layer HTL2 extends onto the partition wall PI which surrounds the third organic EL element OLED3.

The first hole transport layer HTL1 extends over the first to third organic EL elements OLED1 to OLED3, and is disposed on the buffer layer BUF of each of the first organic EL element OLED1 and second organic EL element OLED2 and on the second hole transport layer HTL2 of the third organic EL element OLED3. In addition, the first hole transport layer HTL1 is disposed on the buffer layer BUF above the partition walls PI which are disposed between the first organic EL element OLED1 and the second organic EL element OLED2, between the second organic EL element OLED2 and the third organic EL element OLED3, and between the third organic EL element OLED3 and the first organic EL element OLED1. Specifically, the first hole transport layer HTL1 is a continuous film spreading over the display region and is disposed common to the first to third organic EL elements OLED1 to OLED3.

The first organic layer EM1 is disposed on the first hole transport layer HTL1 of the first organic EL element OLED1. Part of the first organic layer EM1 extends onto the partition wall PI surrounding the first organic EL element OLED1.

The second organic layer EM2 is disposed on the first hole transport layer HTL1 of the second organic EL element OLED2. Part of the second organic layer EM2 extends onto the partition wall PI surrounding the second organic EL element OLED2.

The third organic layer EM3 extends over the third organic EL element OLED3 and the first organic EL element OLED1 which neighbors the third organic EL element OLED3 in the X direction, and is disposed on the first organic layer EM1 of the first organic EL element OLED1 and on the first hole transport layer HTL1 of the third organic EL element OLED3. In addition, the third organic layer EM3 is disposed on the first hole transport layer HTL1 above the partition wall PI between the first organic EL element OLED1 and the third organic EL element OLED3.

The second electron transport layer ETL2 is disposed on the third organic layer EM3 of the third organic EL element OLED3. In addition, part of the second electron transport layer ETL2 extends onto the partition wall PI surrounding the third organic EL element OLED3.

The first electron transport layer ETL1 extends over the first to third organic EL elements OLED1 to OLED3, and is disposed on the third organic layer EM3 of the first organic EL element OLED1, on the second organic layer EM2 of the second organic EL element OLED2, and on the second electron transport layer ETL2 of the third organic EL element OLED3. In addition, the first electron transport layer ETL1 is disposed on the first hole transport layer HTL1 above the partition walls PI which are disposed between the first organic EL element OLED1 and the second organic EL element OLED2 and between the second organic EL element OLED2 and the third organic EL element OLED3. Furthermore, the first electron transport layer ETL1 is disposed on the third organic layer EM3 above the partition wall PI which is disposed between the third organic EL element OLED3 and the first organic EL element OLED1. Specifically, the first electron transport layer ETL1 is a continuous film spreading over the display region and is disposed common to the first to third organic EL elements OLED1 to OLED3.

The counter-electrode CE extends over the first to third organic EL elements OLED1 to OLED3 and is disposed on the first electron transport layer ETL1 of the first to third organic EL elements OLED1 to OLED3. In addition, the counter-electrode CE is disposed on the first electron transport layer ETL1 above the partition walls PI which are disposed between the first organic EL element OLED1 and the second organic EL element OLED2, between the second organic EL element OLED2 and the third organic EL element OLED3, and between the third organic EL element OLED3 and the first organic EL element OLED1. Specifically, the counter-electrode CE is a continuous film spreading over the display region and is disposed common to the first to third organic EL elements OLED1 to OLED3.

Examples of the thicknesses of the first to third organic EL elements OLED1 to OLED3 are shown below. In the first organic EL element OLED1, the total film thickness between the reflective layer PER and the counter-electrode CE is about 120 nm. In the second organic EL element OLED2, the total film thickness between the reflective layer PER and the counter-electrode CE is about 95 nm. In the third organic EL element OLED3, the total film thickness between the reflective layer PER and the counter-electrode CE is about 190 nm.

In the first embodiment, however, because of the restrictions due to the interference structure, in order to secure the color purity of emission light, the total film thickness between the reflective layer PER and the counter-electrode CE in the first organic EL element OLED1 should preferably be set in a range of 110 nm to 130 nm. Similarly, the total film thickness between the reflective layer PER and the counter-electrode CE in the second organic EL element OLED2 should preferably be set in a range of 85 nm to 105 nm, and the total film thickness between the reflective layer PER and the counter-electrode CE in the third organic EL element OLED3 should preferably be set in a range of 182 nm to 202 nm.

Thereby, in the first embodiment, the first organic EL element OLED1 and second organic EL element OLED2 adopt the 0th-order interference structure. The third organic EL element OLED3 adopts the first-order interference structure.

According to the first embodiment, the second hole transport layer HTL2 and second electron transport layer ETL2 are disposed in the third organic EL element OLED3, in addition to the first hole transport layer HTL1 and first electron transport layer ETL1 which extend over the first to third organic EL elements OLED1 to OLED3. Thereby, the third organic EL element OLED3 can adopt the device structure which makes use of the interference effect of the higher order than the first organic EL element OLED1 and second organic EL element OLED2.

Thus, in the third organic EL element OLED3 having the above-described structure, the degree of freedom of design of the third organic EL element OLED3 can be improved. For example, in the case where it is desired to improve the carrier balance and thereby improve the light emission efficiency, there is a method of varying the ratio between the film thickness of the hole transport layer and the film thickness of the electron transport layer. As regards the second hole transport layer HTL2 and second electron transport layer ETL2 which are disposed in the third organic EL element OLED3, the ratio in film thickness between these layers can freely be varied in consideration of the carrier balance which is required for the third organic EL element OLED3. At this time, there is no need to vary the film thicknesses of the first hole transport layer HTL1 and first electron transport layer ETL1, which are provided not only in the third organic EL element OLED3 but also in the first organic EL element OLED1 and second organic EL element OLED2. Therefore, the carrier balance in the third organic EL element OLED3 can be improved without adversely affecting the first organic EL element OLED1 and second organic EL element OLED2. By this improvement of carrier balance, the light emission efficiency of the third organic EL element OLED3 can be enhanced.

According to this first embodiment, the buffer layer BUF, first hole transport layer HTL1, first electron transport layer ETL1 and counter-electrode CE are common layers, and are continuous films spreading over the display region. Thus, when these films are formed by evaporation deposition, there is no need to use a fine mask in which fine openings corresponding to the light emission sections EA1 to EA3 are formed, and the manufacturing cost of the mask can be reduced. In addition, the amount of material, which is deposited on the mask at the time of forming the buffer layer BUF, first hole transport layer HTL1, first electron transport layer ETL1 and counter-electrode CE, decreases, and the efficiency of use of the material for forming these films is enhanced.

Besides, according to the first embodiment, the top-emission-type structure is adopted. Specifically, unlike the structure in which emission light is extracted from the substrate SUB side, emission light can be extracted from the side opposite to the substrate SUB, without restrictions to the aperture ratio due to various thin-film transistors and various wirings which are disposed on the substrate SUB. Therefore, the areas of the light emission sections EA1 to EA3 of the first to third organic EL elements OLED1 to OLED3 can sufficiently be secured, and higher fineness can advantageously be achieved.

In the organic multiplayer structure ORG1 of the first organic EL element OLED1, since the third organic layer EM3, which is disposed between the first organic layer EM1 and the first electron transport layer ETL1, includes the third light-emitting material which has a wider band gap than the first light-emitting material of the first organic layer EM1, the third organic layer EM3 emits no light, or emits substantially no light, and functions as a hole blocking layer. In the meantime, the second light-emitting material, too, has a wider band gap than the first light-emitting material. Thus, the organic multiplayer structure ORG1 of the first organic EL element OLED1 may include a second organic layer EM2 including the second light-emitting material, as a hole blocking layer, between the first organic layer EM1 and the first electron transport layer ETL1. Besides, the organic multiplayer structure ORG1 may include, as hole blocking layers, a second organic layer EM2 and a third organic layer EM3 between the first organic layer EM1 and the first electron transport layer ETL1.

In the first organic EL element OLED1 including the hole blocking layer, the carrier balance can be improved, and the light emission efficiency can be improved. Furthermore, since the third organic layer EM3, which is disposed commonly in the third organic EL element OLED3 and first organic EL element OLED1, is usable for optical path length adjustment, the film thickness of the first organic layer EM1 can be reduced by a degree corresponding to the film thickness of the third organic layer EM3 in the first organic multilayer structure ORG1.

In addition, by the reflowing process, the buffer layer BUF has a function of reducing the influence of foreign matter on the surface of the first to third pixel electrodes PE1 to PE3. Thereby, short-circuit between electrodes and the occurrence of film defects can be suppressed.

Next, a description is given of examples of device variations which can be adopted in the first to third organic EL elements OLED1 to OLED3 in the first embodiment.

For example, in the third organic multiplayer structure ORG3, the second hole transport layer HTL2 may be disposed between the first hole transport layer HTL1 and third organic layer EM3. In addition, in the third organic multiplayer structure ORG3, the second electron transport layer ETL2 may be disposed between the first electron transport layer ETL1 and the counter-electrode CE.

In each of the first to third organic multiplayer structures ORG1 to ORG3, a thin film with a hole injection function, namely, a hole injection layer, may be provided immediately above each of the first to third pixel electrodes PE1 to PE3. Such a hole injection layer can be formed of, e.g. copper phthalocyanine.

Each of the first to third organic multiplayer structures ORG1 to ORG3 may include a thin film with an electron injection function, namely an electron injection layer, between the counter-electrode CE and the first electron transport layer ETL1. Such an electron injection layer can be formed of, e.g. lithium fluoride (LiF).

It should suffice if the counter-electrode CE includes at least a semi-transmissive layer. The structure of the counter-electrode CE is not limited to the above-described single-layer structure consisting of only the semi-transmissive layer. The counter-electrode CE may have a structure in which a transmissive layer is further stacked on the semi-transmissive layer.

On the counter-electrode CE, where necessary, a light-transmissive insulation film, such as a silicon oxynitride (SiON) film, may be disposed. Such an insulation film is usable as a protection film for protecting the first to third organic EL elements OLED1 to OLED3, or as a film which adjusts the optical path length for optimizing optical interference.

In the first organic multilayer structure ORG1, the third organic layer EM3 functioning as the hole blocking layer may be omitted. In addition, in each of the first to third organic multilayer structures ORG1 to ORG3, the buffer layer BUF may be omitted.

It is desirable that the first hole transport layer HTL1 and second hole transport layer HTL2 be formed of materials having different hole mobilities. The carrier balance in the third organic multilayer structure ORG3 can be improved by combining a material having a high hole mobility and a material having a low hole mobility and optimizing the ratio in thickness between these materials. In the case of the illustrated example in which the first hole transport layer HTL1 is disposed between the second hole transport layer HTL2 and third organic layer EM3, the first hole mobility of the first hole transport layer HTL1 is lower than the second hole mobility of the second hole transport layer HTL2.

Similarly, it is desirable that the first electron transport layer ETL1 and second electron transport layer ETL2 be formed of materials having different electron mobilities. The carrier balance in the third organic multilayer structure ORG3 can be improved by combining a material having a high electron mobility and a material having a low electron mobility and optimizing the ratio in thickness between these materials. In the case of the illustrated example in which the first electron transport layer ETL1 is disposed between the second electron transport layer ETL2 and counter-electrode CE, the first electron mobility of the first electron transport layer ETL1 is lower than the second electron mobility of the second electron transport layer ETL2.

Next, other variations of the first embodiment are described.

As has been described above, the third organic multilayer structure ORG3 includes the first hole transport layer HTL1 and second hole transport layer HTL2 between the third pixel electrode PE3 and the third organic layer EM3. The first hole transport layer HTL1 is stacked on the second hole transport layer HTL2. The first hole transport layer HTL1 and second hole transport layer HTL2 are formed of materials having different refractive indices.

Part of emission light from the third organic layer EM3 is reflected at an interface between the first hole transport layer HTL1 and second hole transport layer HTL2 having different refractive indices. In other words, the interface between the first hole transport layer HTL1 and second hole transport layer HTL2 functions as a reflective surface. Thus, with respect to the light emitted from the third organic layer EM3, the phase of reflective light, which is reflected by the reflective layer PER of the third pixel electrode PE3, and the phase of reflective light, which is reflected by the interface between the first hole transport layer HTL1 and second hole transport layer HTL2, are matched so as to mutually strengthen these respective reflective light components. Thereby, the light emission efficiency of the third organic EL element OLED3 can be improved. The phases of the reflective light components can be adjusted by the ratio in refractive index between the first hole transport layer HTL1 and second hole transport layer HTL2, and the ratio in film thickness between the first hole transport layer HTL1 and second hole transport layer HTL2.

Simulations were conducted with respect to the variation of the light emission efficiency of the third organic EL element OLED3 in the case where the refractive index ratio n1/n2 and the film thickness ratio x/y were varied, wherein n1 is the refractive index of the first hole transport layer HTL1, n2 is the refractive index of the second hole transport layer HTL2, x is the film thickness of the first hole transport layer HTL1, and y is the film thickness of the second hole transport layer HTL2.

The case was assumed in which the major wavelength of the emission light spectrum of the third organic layer EM3 in the third organic EL element OLED3 is 470 nm. By an optical simulator, the frontal luminance of the display panel DP was calculated, and the light emission efficiency (cd/A) was found. The light emission efficiency corresponds to the emission light luminance relative to the unit injection current density.

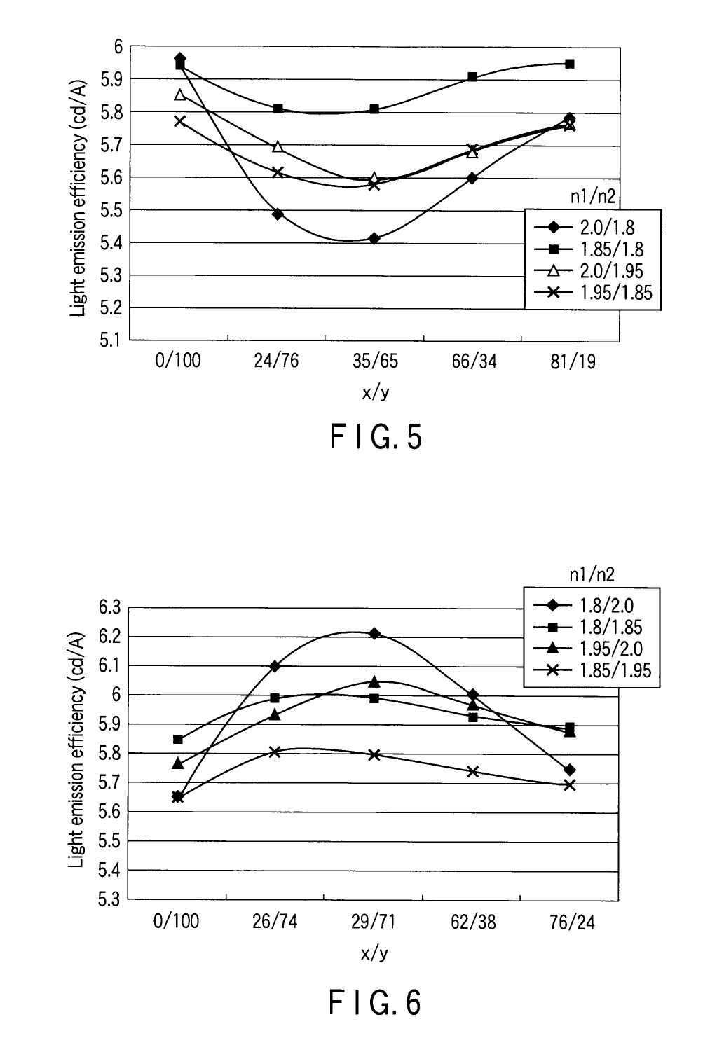

In a first simulation, the light emission efficiency relative to the film thickness ratio x/y was found in the case where n1 is greater than n2. FIG. 5 shows a simulation result of four cases where the refractive index ratio n1/n2 is 2.0/1.8, 1.85/1.8, 2.0/1.95, and 1.95/1.85.

As shown in FIG. 5, compared to the case where the film thickness x of the first hole transport layer HTL1 is zero, the light emission efficiency gradually decreases as the ratio of the film thickness x of the first hole transport layer HTL1 to the film thickness y of the second hole transport layer HTL2 increases. If the ratio of the film thickness x of the first hole transport layer HTL1 further increases and the film thickness x of the first hole transport layer HTL1 becomes greater than the film thickness y of the second hole transport layer HTL2, the light emission efficiency begins to increase. The same tendency was confirmed with respect to all the four cases of the refractive index ratio n1/n2. Although not shown, in the case where n1 is greater than n2, the same tendency, in general, was confirmed.

From the result of the first simulation, it was confirmed that, when n1 is greater than n2, the film thickness ratio x/y should preferably be set at a value at which the light emission efficiency recovers by 2.5% or more from the bottom of light emission efficiency, and that a relatively high light emission efficiency could be obtained when the ratio of the film thickness x of the first hole transport layer HTL1 to the total film thickness (x+y) of the first hole transport layer HTL1 and second hole transport layer HTL2 is 30% or less, or 65% or more.

In a second simulation, the light emission efficiency relative to the film thickness ratio x/y was found in the case where n1 is less than n2. FIG. 6 shows a simulation result of four cases where the refractive index ratio n1/n2 is 1.8/2.0, 1.8/1.85, 1.95/2.0, and 1.85/1.95.

As shown in FIG. 6, compared to the case where the film thickness x of the first hole transport layer HTL1 is zero, the light emission efficiency gradually increases as the ratio of the film thickness x of the first hole transport layer HTL1 to the film thickness y of the second hole transport layer HTL2 increases. If the ratio of the film thickness x of the first hole transport layer HTL1 further increases and the film thickness x of the first hole transport layer HTL1 becomes greater than the film thickness y of the second hole transport layer HTL2, the light emission efficiency begins to decrease. The same tendency was confirmed with respect to all the four cases of the refractive index ratio n1/n2. Although not shown, in the case where n1 is less than n2, the same tendency, in general, was confirmed.

From the result of the second simulation, it was confirmed that, when n1 is less than n2, the film thickness ratio x/y should preferably be set at a value at which the decrease in light emission efficiency can be suppressed to 2.5% or less from the peak of light emission efficiency, and that a relatively high light emission efficiency could be obtained when the ratio of the film thickness x of the first hole transport layer HTL1 to the total film thickness (x+y) of the first hole transport layer HTL1 and second hole transport layer HTL2 is 30% or more and 65% or less.

These ranges correspond to ranges in which the reflective light, which is reflected by the interface between the first hole transport layer HTL1 and second hole transport layer HTL2, and other reflective light, strengthen each other by interference.

Next, a second embodiment is described. The second embodiment differs from the first embodiment in that a second organic layer EM2 is disposed between the first organic layer EM1 and third organic layer EM3 in the first organic EL element OLED1, that a third organic layer EM3 is disposed between the second organic layer EM2 and electron transport layer ETL in the second organic EL element OLED2, and that a first organic layer EM1 and a second organic layer EM2 are disposed between the first hole transport layer HTL1 and second hole transport layer HTL2 and the second electron transport layer is omitted in the third organic EL element OLED3.

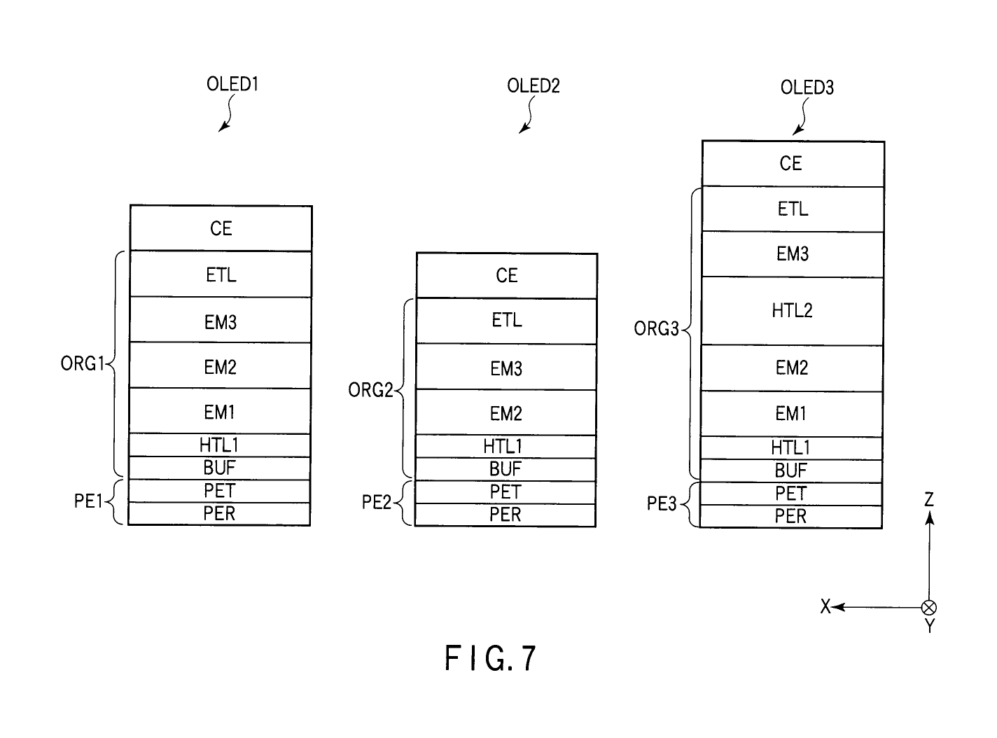

FIG. 7 schematically shows the structures of first to third organic EL elements OLED1 to OLED3 in the second embodiment. The structural parts common to those in the first embodiment shown in FIG. 3 are denoted by like reference numerals, and a detailed description thereof is omitted.

The first organic EL element OLED1 includes a first organic multilayer structure ORG1 between a first pixel electrode PE1 and a counter-electrode CE. Specifically, the first pixel electrode PE1 includes a reflective layer PER and a transmissive layer PET which is disposed on the reflective layer PER. The first organic multilayer structure ORG1 is disposed on the first pixel electrode PE1. The first organic multilayer structure ORG1 includes a buffer layer BUF which is disposed on the transmissive layer PET, a first hole transport layer HTL1 which is disposed on the buffer layer BUF, a first organic layer EM1 which is disposed on the first hole transport layer HTL1 and functions as a light emission layer, a second organic layer EM2 which is disposed on the first organic layer EM1 and functions as a carrier transport layer, a third organic layer EM3 which is disposed on the second organic layer EM2 and functions as a carrier transport layer, and an electron transport layer ETL which is disposed on the third organic layer EM3. The counter-electrode CE is disposed on the electron transport layer ETL of the first organic multilayer structure ORG1.

The second organic EL element OLED2 includes a second organic multilayer structure ORG2 between a second pixel electrode PE2 and a counter-electrode CE. Specifically, the second pixel electrode PE2 includes a reflective layer PER and a transmissive layer PET which is disposed on the reflective layer PER. The second organic multilayer structure ORG2 is disposed on the second pixel electrode PE2. The second organic multilayer structure ORG2 includes a buffer layer BUF which is disposed on the transmissive layer PET, a first hole transport layer HTL1 which is disposed on the buffer layer BUF, a second organic layer EM2 which is disposed on the first hole transport layer HTL1 and functions as a light emission layer, a third organic layer EM3 which is disposed on the second organic layer EM2 and functions as a carrier transport layer, and an electron transport layer ETL which is disposed on the third organic layer EM3. The counter-electrode CE is disposed on the electron transport layer ETL of the second organic multilayer structure ORG2.

The third organic EL element OLED3 includes a third organic multilayer structure ORG3 between a third pixel electrode PE3 and a counter-electrode CE. Specifically, the third pixel electrode PE3 includes a reflective layer PER and a transmissive layer PET which is disposed on the reflective layer PER. The third organic multilayer structure ORG3 is disposed on the third pixel electrode PE3. The third organic multilayer structure ORG3 includes a buffer layer BUF which is disposed on the transmissive layer PET, a first hole transport layer HTL1 which is disposed on the buffer layer BUF, a first organic layer EM1 which is disposed on the first hole transport layer HTL1 and functions as a carrier transport layer, a second organic layer EM2 which is disposed on the first organic layer EM1 and functions as a carrier transport layer, a second hole transport layer HTL2 which is disposed on the second organic layer EM2, a third organic layer EM3 which is disposed on the second hole transport layer HTL2 and functions as a light emission layer, and an electron transport layer ETL which is disposed on the third organic layer EM3. The counter-electrode CE is disposed on the electron transport layer ETL of the third organic multilayer structure ORG3.

The same materials as described in the first embodiment, for example, may be used as materials of the first to third pixel electrodes PE1 to PE3, the buffer layer BUF, the first to third organic layers EM1 to EM3, the first hole transport layer HTL1 and second hole transport layer HTL2, the electron transport layer ETL, and the counter-electrode CE.

In the first organic EL element OLED1, since the first organic layer EM1 functions as a light emission layer, the first organic EL element OLED1 emits red light having an emission light wavelength in the first wavelength band. In the first organic EL element OLED1, the second organic layer EM2 and third organic layer EM3 emit no light, or emit substantially no light.

In the second organic EL element OLED2, since the second organic layer EM2 functions as a light emission layer, the second organic EL element OLED2 emits green light having an emission light wavelength in the second wavelength band. In the second organic EL element OLED2, the third organic layer EM3 emits no light, or emits substantially no light.

In the third organic EL element OLED3, since the third organic layer EM3 functions as a light emission layer, the third organic EL element OLED3 emits blue light having an emission light wavelength in the third wavelength band. In the third organic EL element OLED3, the first organic layer EM1 and second organic layer EM2 emit no light, or emit substantially no light.

In the second embodiment, too, the thickness of the second organic EL element OLED2 is less than that of the first organic EL element OLED1. The thickness of the third organic EL element OLED3 is greater than that of the first organic EL element OLED1. In the above-described structure, the first organic EL element OLED 1 and the second organic EL element OLED2 may adopt device structures which make use of the interference effect of the same order. For example, the first organic EL element OLED 1 and the second organic EL element OLED2 may adopt device structures which make use of the interference effect of a 0th order. The third organic EL element OLED3 may adopt a device structure which makes use of the interference effect of a higher order than the first organic EL element OLED 1 and the second organic EL element OLED2. For example, the third organic EL element OLED3 may adopt a device structure which makes use of the interference effect of a first order.

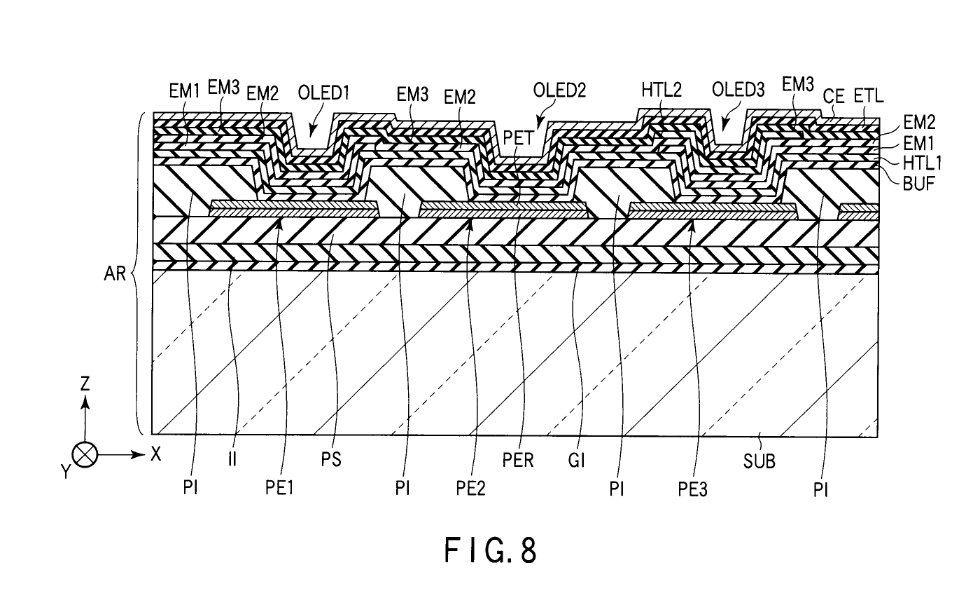

FIG. 8 schematically shows the cross-sectional structure of the array substrate AR including the first to third organic EL elements OLED1 to OLED3 according to the second embodiment. FIG. 8 shows the cross-sectional structure which does not include the switching transistors SW.

As shown in FIG. 8, the gate insulation film GI, interlayer insulation film II and passivation film PS are disposed between the substrate SUB and the reflective layer PER of each of the first to third organic EL elements OLED1 to OLED3. The reflective layer PER of each of the first to third pixel electrodes PE1 to PE3 is disposed on the passivation film PS. The transmissive layer PET of each of the first to third organic EL elements OLED1 to OLED3 is disposed on the reflective layer PER.

The buffer layer BUF extends over the first to third organic EL elements OLED1 to OLED3 and is disposed on the transmissive layer PET of the first pixel electrode PE1, the transmissive layer PET of the second pixel electrode PE2 and the transmissive layer PET of the third pixel electrode PE3. In addition, the buffer layer BUF is disposed on the partition wall PI which is disposed between the first organic EL element OLED1 and the second organic EL element OLED2, between the second organic EL element OLED2 and the third organic EL element OLED3, and between the third organic EL element OLED3 and the first organic EL element OLED1.

The first hole transport layer HTL1 extends over the first to third organic EL elements OLED1 to OLED3, and is disposed on the buffer layer BUF of each of the first to third organic EL elements OLED1 to OLED3. In addition, the first hole transport layer HTL1 is disposed on the buffer layer BUF above the partition walls PI which are disposed between the first organic EL element OLED1 and the second organic EL element OLED2, between the second organic EL element OLED2 and the third organic EL element OLED3, and between the third organic EL element OLED3 and the first organic EL element OLED1.

The first organic layer EM1 extends over the first organic EL element OLED1 and the third organic EL element OLED3 which neighbors the first organic EL element OLED1 in the X direction, and is disposed on the first hole transport layer HTL1 of each of the first organic EL element OLED1 and third organic EL element OLED3. In addition, the first organic layer EM1 is disposed on the first hole transport layer HTL1 above the partition wall PI between the first organic EL element OLED1 and the third organic EL element OLED3.

The second organic layer EM2 extends over the first to third organic EL elements OLED1 to OLED3, and is disposed on the first hole transport layer HTL1 of the second organic EL element OLED2 and on the first organic layer EM1 of each of the first organic EL element OLED1 and third organic EL element OLED3. In addition, the second organic layer EM2 is disposed on the first hole transport layer HTL1 above the partition walls PI between the first organic EL element OLED1 and the second organic EL element OLED2 and between the second organic EL element OLED2 and third organic EL element OLED3. Furthermore, the second organic layer EM2 is disposed on the first organic layer EM1 above the partition wall PI between the third organic EL element OLED3 and first organic EL element OLED1.

The second hole transport layer HTL2 is disposed on the second organic layer EM2 of the third organic EL element OLED3. Part of the second hole transport layer HTL2 extends onto the partition wall PI which surrounds the third organic EL element OLED3.

The third organic layer EM3 extends over the first to third organic EL elements OLED1 to OLED3, and is disposed on the second hole transport layer HTL2 of the third organic EL element OLED3 and on the second organic layer EM2 of each of the first organic EL element OLED1 and second organic EL element OLED2. In addition, the third organic layer EM3 is disposed on the second organic layer EM2 above the partition walls PI which are disposed between the first organic EL element OLED1 and the second organic EL element OLED2, between the second organic EL element OLED2 and the third organic EL element OLED3, and between the third organic EL element OLED3 and the first organic EL element OLED1.

The electron transport layer ETL extends over the first to third organic EL elements OLED1 to OLED3, and is disposed on the third organic layer EM3 of each of the first to third organic EL elements OLED1 to OLED3. In addition, the electron transport layer ETL is disposed on the third organic layer EM3 above the partition walls PI which are disposed between the first organic EL element OLED1 and the second organic EL element OLED2, between the second organic EL element OLED2 and the third organic EL element OLED3, and between the third organic EL element OLED3 and the first organic EL element OLED1.

The counter-electrode CE extends over the first to third organic EL elements OLED1 to OLED3 and is disposed on the electron transport layer ETL of each of the first to third organic EL elements OLED1 to OLED3. In addition, the counter-electrode CE is disposed on the electron transport layer ETL above the partition walls PI which are disposed between the first organic EL element OLED1 and the second organic EL element OLED2, between the second organic EL element OLED2 and the third organic EL element OLED3, and between the third organic EL element OLED3 and the first organic EL element OLED1.

According to the second embodiment, the same advantageous effects as with the first embodiment can be obtained.

Besides, according to the second embodiment, the second organic layer EM2 and third organic layer EM3, in addition to the buffer layer BUF, first hole transport layer HTL1, electron transport layer ETL and counter-electrode CE, are common layers and are continuous films spreading over the display region. Thus, when these films are formed by evaporation deposition, there is no need to use a fine mask in which fine openings corresponding to the light emission sections EA1 to EA3 are formed, and the manufacturing cost of the mask can be reduced. In the second embodiment, it should suffice if two fine masks are prepared for forming the second hole transport layer HTL2 of the third organic EL element OLED3, and the first organic layer EM1 that is common to the first organic EL element OLED1 and third organic EL element OLED3.

Compared to the case where fine masks are needed, the amount of material, which is deposited on the masks at the time of forming the buffer layer BUF, first hole transport layer HTL1, electron transport layer ETL, counter-electrode CE, second organic layer EM2 and third organic layer EM3, decreases, and the efficiency of use of the material for forming these films is enhanced.

In the second embodiment, too, the device variations, which have been described in connection with the first embodiment, can be adopted.

Like the first embodiment, in the third organic EL element OLED3, the electron transport layer ETL may be configured to have a two-layer structure. In this case, for example, in the third organic multilayer structure ORG3, a second electron transport layer ETL2 may be disposed between the third organic layer EM3 and electron transport layer ETL or between the electron transport layer ETL and counter-electrode CE. By adding the second electron transport layer ETL2, the film thickness of the second hole transport layer HTL2, which has been described in the second embodiment, can be reduced.

In the second embodiment, the first organic layer EM1 and second organic layer EM2 between the first hole transport layer HTL1 and second hole transport layer HTL2 substantially function as hole transport layers. Thus, as has been described in connection with the other variations of the first embodiment, the interface between the first hole transport layer HTL1 and first organic layer EM1, between the first organic layer EM1 and second organic layer EM2 or between the second organic layer EM2 and second hole transport layer HTL2 is usable as a reflective surface. Thus, by adjusting the ratio in refractive index and the ratio in film thickness between the two layers sandwiching the interface functioning as the reflective surface, the phase of reflective surface, which is reflected by the interface, and the phase of reflective light, which is reflected by the reflective layer PER, can be matched so as to mutually strengthen the respective reflective light components. Thereby, the light emission efficiency of the third organic EL element OLED3 can be improved.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

In the above-described embodiments, all the first to third light-emitting materials included in the first to third organic layers EM1 to EM3 may be fluorescent materials or phosphorescent materials. Alternatively, one or two of the first to third light-emitting materials may be a fluorescent material or fluorescent materials, and the other two or one may be phosphorescent materials or a phosphorescent material.

Each of the above-described embodiments may include either an electron injection layer or a hole injection layer, or both the electron injection layer and hole injection layer.

In the embodiments, the organic EL display device has been described as the organic EL device. However, the organic EL device is applicable to organic EL illuminations, organic EL printer heads, etc.

What is claimed is:

1. An organic EL device comprising:
a first organic EL element having a first light emission wavelength, the first organic EL element including A) a first pixel electrode, B) a counter-electrode, and C) a first organic multiplayer structure including a first organic layer disposed between the first pixel electrode and the counter-electrode and functioning as a light emission layer, a first hole transport layer disposed between the first pixel electrode and the first organic layer, and a first electron transport layer disposed between the first organic layer and the counter-electrode;
a second organic EL element having a less thickness than the first organic EL element and having a second light emission wavelength which is less than the first light emission wavelength, the second organic EL element including A) a second pixel electrode, B) the counter-electrode extending from the first organic EL element, and C) a second organic multiplayer structure including a second organic layer disposed between the second pixel electrode and the counter-electrode and functioning as a light emission layer, the first hole transport layer extending from the first organic EL element and disposed between the second pixel electrode and the second organic layer, and the first electron transport layer extending from the first organic EL element and disposed between the second organic layer and the counter-electrode; and
a third organic EL element having a greater thickness than the first organic EL element and having a third light emission wavelength which is less than the second light emission wavelength, the third organic EL element including A) a third pixel electrode, B) the counter-electrode extending from the second organic EL element, and C) a third organic multiplayer structure including a third organic layer disposed between the third pixel electrode and the counter-electrode and functioning as a light emission layer, the first hole transport layer extending from the second organic EL element and disposed between the third pixel electrode and the third organic layer, a second hole transport layer disposed between the third pixel electrode and the third organic layer, the first electron transport layer extending from the second organic EL element and disposed between the third organic layer and the counter-electrode, and a second electron transport layer disposed between the third organic layer and the counter-electrode.

2. The organic EL device of claim 1, wherein a first hole mobility of the first hole transport layer is different from a second hole mobility of the second hole transport layer.

3. The organic EL device of claim 1, wherein the first hole transport layer is disposed between the second hole transport layer and the third organic layer.

4. The organic EL device of claim 3, wherein a first hole mobility of the first hole transport layer is lower than a second hole mobility of the second hole transport layer.

5. The organic EL device of claim 1, wherein a first electron mobility of the first electron transport layer is different from a second electron mobility of the second electron transport layer.

6. The organic EL device of claim 1, wherein the first electron transport layer is disposed between the second electron transport layer and the counter-electrode.

7. The organic EL device of claim 6, wherein a first electron mobility of the first electron transport layer is lower than a second electron mobility of the second electron transport layer.

8. The organic EL device of claim 1, wherein a refractive index of the first hole transport layer is different from a refractive index of the second hole transport layer.

9. The organic EL device of claim 1, wherein the first organic multilayer structure further includes the third organic layer extending from the third organic EL element and disposed between the first organic layer and the first electron transport layer.

10. The organic EL device of claim 1, wherein the first pixel electrode includes a first reflective layer, the second pixel electrode includes a second reflective layer, and the third pixel electrode includes a third reflective layer.

11. The organic EL device of claim 1, wherein the counter-electrode includes a semi-transmissive layer.

12. The organic EL device of claim 1, wherein at least one of the first to third organic layers includes a phosphorescent material.

13. The organic EL device of claim 1, further comprising a protection layer covering the first to third organic EL elements, a counter-substrate disposed above the protection layer, and a filling layer filled between the protection film and the counter-substrate.

14. An organic EL device comprising:
a first organic EL element having a first light emission wavelength, the first organic EL element including A) a first pixel electrode, B) a counter-electrode, and C) a first organic multiplayer structure including a first organic layer disposed between the first pixel electrode and the counter-electrode and functioning as a light emission layer, a first hole transport layer disposed between the first pixel electrode and the first organic layer, a second organic layer disposed between the first organic layer and the counter-electrode and functioning as a carrier transport layer, and a third organic layer disposed between the second organic layer and the counter-electrode and functioning as a carrier transport layer;
a second organic EL element having a second light emission wavelength which is less than the first light emission wavelength, the second organic EL element including A) a second pixel electrode, B) the counter-electrode extending from the first organic EL element, and C) a second organic multiplayer structure including the second organic layer extending from the first organic EL element, disposed between the second pixel electrode and the counter-electrode and functioning as a light emission layer, the first hole transport layer extending from the first organic EL element and disposed between the second pixel electrode and the second organic layer, and the third organic layer extending from the first organic EL element, disposed between the second organic layer and the counter-electrode and functioning as a carrier transport layer; and
a third organic EL element having a third light emission wavelength which is less than the second light emission wavelength, the third organic EL element including A) a third pixel electrode, B) the counter-electrode extending from the second organic EL element, and C) a third organic multiplayer structure including the first organic layer extending from the first organic EL element, disposed between the third pixel electrode and the counter-electrode and functioning as a carrier transport layer, a first hole transport layer extending from the second organic EL element and disposed between the third pixel electrode and the first organic layer, the second organic layer extending from the second organic EL element, disposed between the first organic layer and the counter-electrode and functioning as a carrier transport layer, a second hole transport layer disposed between the second organic layer and the counter-electrode, and the third organic layer extending from the second organic EL element, disposed between the second hole transport layer and the counter-electrode and functioning as a light emission layer.

15. The organic EL device of claim 14, wherein the second organic EL element has a less thickness than the first organic EL element, and the third organic EL element has a greater thickness than the first organic EL element.

16. The organic EL device of claim 14, wherein each of the first to third organic multilayer structures includes an electron transport layer between the third organic layer and the counter-electrode.

17. The organic EL device of claim 14, wherein the first pixel electrode includes a first reflective layer, the second pixel electrode includes a second reflective layer, and the third pixel electrode includes a third reflective layer.

18. The organic EL device of claim 14, wherein the counter-electrode includes a semi-transmissive layer.

19. The organic EL device of claim 14, wherein at least one of the first to third organic layers includes a phosphorescent material.

20. The organic EL device of claim 14, further comprising a protection layer covering the first to third organic EL elements, a counter-substrate disposed above the protection layer, and a filling layer filled between the protection film and the counter-substrate.
